(19) United States
(12) Patent Application Publication
(10) Pub. No.: US 2026/0096416 A1
(43) Pub. Date: Apr. 2, 2026

(54) Power Grid Architecture

(71) Applicant: Apple Inc., Cupertino, CA (US)

(72) Inventors: Praveen Raghavan, Cupertino, CA (US); Kapil K. Kothari, Fremont, CA (US); Abhimanyu Sharma, San Francisco, CA (US); Hankyeol Bae, San Jose, CA (US); Sateesh V. Medepalli, San Jose, CA (US); Ofir Elster, Raanana (IL)

(21) Appl. No.: 19/072,630

(22) Filed: Mar. 6, 2025

Related U.S. Application Data
(60) Provisional application No. 63/699,893, filed on Sep. 27, 2024.

(51) Int. Cl. H01L 23/528; H01L 23/522

(52) U.S. Cl. CPC H10W 20/427; H10W 20/42

(57) ABSTRACT

Power grid routings that provide connectivity between power supply sources, power switch circuits, and functional circuits in integrated circuit devices are described. The power grid routings include routings for actual power supply voltage (TVDD) from the power supply source to the power switches in a power switch region of the device and converted power supply voltages (VVDD) from the power switches to the functional circuits in a core logic region of the device. Routings for ground supply voltage are also described. The routings may include certain combinations of pillar routings (e.g., primarily vertical current transfer routings) and mesh routings (e.g., horizontally distributed routings) in the topside metal layers above the transistor region of the device.

### PRIORITY CLAIM

The present application claims priority to U.S. Provisional App. No. 63/699,893, entitled “Power Grid Architecture,” filed Sep. 27, 2024, the disclosure of which is incorporated by reference herein in its entirety.

### BACKGROUND

### Technical Field

Embodiments described herein relate to power and signal routing for semiconductor devices. More particularly, embodiments described herein relate to implementations for power grid routing through power switches between a power supply and functional circuits.

### Description of the Related Art

Power switch circuits are important in large scale integrations of integrated circuits (such as very-large scale integrations (VLSIs)). For instance, power switches are implemented to convert true power supply voltages (e.g., true VDD or TVDD) provided by power supplies to virtual power supply voltages that are tailored for specific devices. In many instances, power switch devices are placed between functional circuits in a core logic region of a device and the power supply source. The connectivity involving devices with power switches includes routings for TVDD, VVDD (e.g., the converted power supply voltage), and VSS (e.g., the ground supply voltage). These routings may involve long paths that utilize large amounts of resources in the power switch region and the core logic region around the functional circuits. Accordingly, there are both electrical and mechanical reasons for optimizing the utilization of physical resources when implementing the various routings for TVDD, VVDD, and VSS.

### BRIEF DESCRIPTION OF THE DRAWINGS

Features and advantages of the methods and apparatus of the embodiments described in this disclosure will be more fully appreciated by reference to the following detailed description of presently preferred but nonetheless illustrative embodiments in accordance with the embodiments described in this disclosure when taken in conjunction with the accompanying drawings in which:

FIG. 1 depicts a schematic side-view representation of an implementation of power switches in an integrated circuit device, according to some embodiments.

FIG. 2 depicts a side-view representation of a power switch region in a transistor region above a substrate, according to some embodiments.

FIG. 3A depicts a side-view representation of pillar routing, according to some embodiments.

FIG. 3B depicts a top plan view representation of pillar routing, according to some embodiments.

FIG. 4A depicts a side-view representation of mesh routing, according to some embodiments.

FIG. 4B depicts a top plan view representation of mesh routing, according to some embodiments.

FIG. 5 depicts a side-view representation of TVDD routing over a power switch region of a device, according to some embodiments.

FIG. 6 depicts a side-view representation of TVDD routing over a core logic region of a device, according to some embodiments.

FIG. 7 depicts a side-view representation of VVDD routing over a power switch region of a device, according to some embodiments.

FIG. 8 depicts a side-view representation of VVDD routing over a core logic region of a device, according to some embodiments.

FIG. 9 depicts another side-view representation of VVDD routing over a power switch region of a device.

FIG. 10 depicts another side-view representation of VVDD routing over a core logic region of a device, according to some embodiments.

FIG. 11 depicts a side-view representation of VSS routing over a power switch region of a device, according to some embodiments.

FIG. 12 depicts a side-view representation of VSS routing over a core logic region of a device, according to some embodiments.

FIG. 13 depicts a side-view representation of an alternative embodiment of VSS routing over a power switch region of a device.

FIG. 14 depicts a side-view representation of an alternative embodiment of VSS routing over a core logic region of a device.

FIG. 15 depicts a side-view representation of VSS routing over a power switch region of a device that is substantially similar to VSS routing in FIG. 13.

FIG. 16 depicts a side-view representation of another alternative embodiment of VSS routing over a core logic region of a device.

FIG. 17 is a cross-sectional side-view representation of a beginning manufacturing step for forming routing on a substrate, according to some embodiments.

FIG. 18 is a cross-sectional side-view representation of a manufacturing step for forming mesh routing on a substrate, according to some embodiments

FIG. 19 is a cross-sectional side-view representation of a manufacturing step for forming pillar routing on a substrate, according to some embodiments.

FIG. 20 is a cross-sectional side-view representation of a manufacturing step for forming vias on mesh routing, according to some embodiments.

FIG. 21 is a cross-sectional side-view representation of a manufacturing step for forming mesh routing on mesh routing, according to some embodiments.

FIG. 22 is a cross-sectional side-view representation of a manufacturing step for forming pillar routing on mesh routing, according to some embodiments.

FIG. 23 is a cross-sectional side-view representation of a manufacturing step for forming vias on pillar routing, according to some embodiments.

FIG. 24 is a cross-sectional side-view representation of a manufacturing step for forming pillar routing on pillar routing, according to some embodiments.

FIG. 25 is a cross-sectional side-view representation of a manufacturing step for forming mesh routing on pillar routing, according to some embodiments.

FIG. 26 is a block diagram of one embodiment of an example system.

Although the embodiments disclosed herein are susceptible to various modifications and alternative forms, specific embodiments are shown by way of example in the drawings and are described herein in detail. It should be understood, however, that drawings and detailed description thereto are not intended to limit the scope of the claims to the particular forms disclosed. On the contrary, this application is intended to cover all modifications, equivalents and alternatives falling within the spirit and scope of the disclosure of the present application as defined by the appended claims.

### DETAILED DESCRIPTION OF EMBODIMENTS

The present disclosure is directed to the implementation of connectivity between power supply sources, power switch circuits, and functional circuits in integrated circuit devices. Specifically, the connectivity involves routings of the actual power supply voltage (referred to, herein, as “true power supply voltage” or “TVDD”) from a power supply source to power switches, routings of lower supply voltages (referred to, herein, as “virtual power supply voltages” or “VVDDs”) from the power switches to specific functional circuits, and routings of ground supply voltage (referred to, herein, as “ground supply voltage” or “VSS”) from the power supply source to the functional circuits.

As used herein, the term “routing” refers to any combination of metal vias, metal wires, metal traces, terminals, etc. that provide a path/route between two structures. Additional embodiments may be contemplated where the metal in “routing” is replaced with an alternative conductive material. For instance, the metal in “routing” may be replaced with a superconductor material, a semiconductor material, or a non-metal conductor. Routings may be part of a “power grid” or a “power network” for a particular voltage. For instance, a power grid/network for TVDD includes the various routings for TVDD between the power supply source and the power switches.

Power switch circuits are implemented in many current iterations of VLSI (“very large scale integration”) devices. For low power VLSI devices, power switch circuits are essential in converting higher power supply voltages to lower operating voltages for specific circuits (such as functional circuits) in the VLSI. For instance, power switch circuits may convert the actual power supply voltage (“TVDD”) from a power supply source to a lower supply voltage (“VVDD”) that is usable for operation of a specific circuit (e.g., a specific functional circuit) in a core logic region of a device.

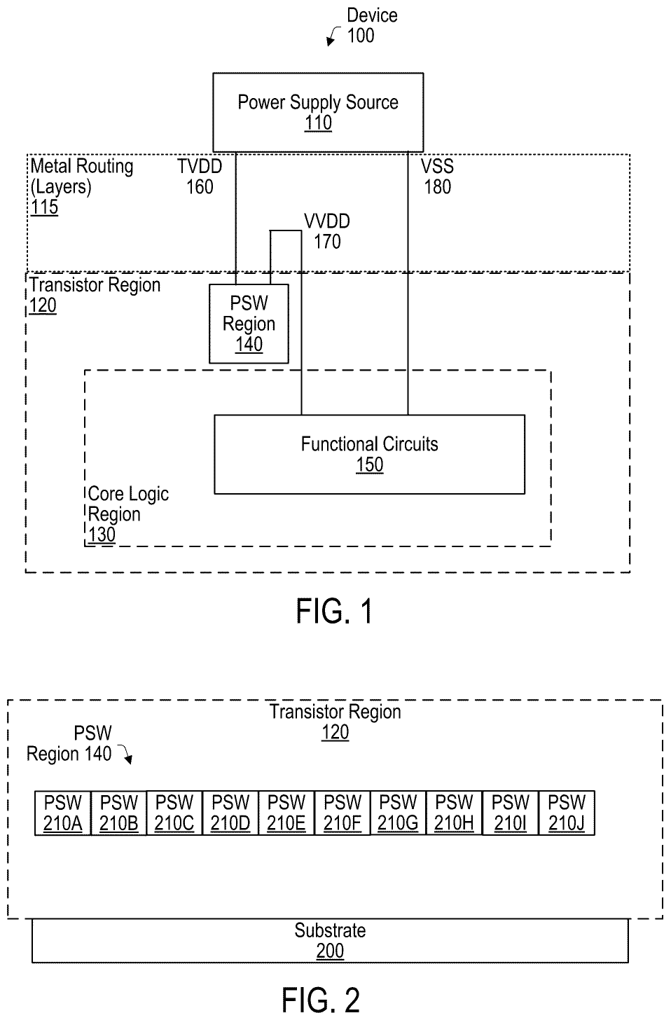

FIG. 1 depicts a schematic side-view representation of an implementation of power switches in an integrated circuit device, according to some embodiments. Integrated circuit device 100 may be, for example, a VLSI device. In the illustrated embodiment, integrated circuit device 100 includes power supply source 110 and transistor region 120. Transistor region 120 includes core logic region 130 and power switch (PSW) region 140. In some embodiments, core logic region 130 may be referred to as a switched logic region or a gated logic region. Functional circuits 150 may be positioned in core logic region 130. Functional circuits 150 may include various active circuits that receive converted power supply voltages (e.g., VVDD) from power switches in power switch region 140. Examples of functional circuits include, but are not limited to, switched logic circuits or gated logic circuits. It should be noted that the various regions of device 100 are shown schematically and that no specific position of one region relative to another region is implied by the placements of the regions in FIG. 1.

As shown in FIG. 1, power switch region 140 is located in transistor region 120 of device 100 along with core logic region 130 and functional circuits 150. In various embodiments, power switch region 140 includes a plurality of power switch circuits. FIG. 2 depicts a side-view representation of a power switch region in a transistor region above a substrate, according to some embodiments. In the illustrated embodiment, power switch region 140 includes a plurality of power switches (PSWs) 210A-J formed in transistor region 120 above substrate 200. Power switches 210 may be, for example, FET (field-effect transistor) power switches or other types of integrated circuit power switches capable of switching or converting voltages.

In certain embodiments, as shown in FIG. 2, power switches 210A-J are an array of power switches aligned in a horizontal dimension above substrate 200 in transistor region 120. For instance, power switches 210A-J may be aligned linearly in the horizontal dimension above substrate 200. Power switches 210A-J may be positioned at any distance above substrate 200 in transistor region 120. In some embodiments, transistor region 120 may include multiple power regions 140 with each power region having multiple power switches. The multiple power regions 140 may be spaced at different heights and in different horizontal positions relative to substrate 200.

In various embodiments, power switch circuits 210 in power switch region 140 may convert TVDD (the true power supply voltage from power supply source 110) to one or more VVDDs (virtual power supply voltages specific to functional circuits 150 in core logic region 130). Meanwhile, as shown in FIG. 1, the ground supply voltage (VSS) may be provided directly from power supply source 110 to functional circuits 150 without any change in the voltage. In some embodiments, the ground supply voltage (VSS) may also be routed to power switch circuits 210, as described herein.

With both power switch region 140 and core logic region 130 positioned in transistor region 120 of device 100, there are various pathways of routings for each of the three power networks—TVDD power network 160, VVDD power network 170, and VSS power network 180—through the transistor region. In certain embodiments, metal routing 115 (e.g., layers of metal routing) is positioned between power supply source 110 and transistor region 120. Metal routing 115 may include the various layers or sets of layers of power network routing for TVDD 160, VVDD 170, and VSS 180. In certain embodiments, metal routing 115 is located in topside (e.g., BEOL) metal layers above transistor region 120. While power switch region 140 may represent only a small amount of the resources in the transistor region (e.g., 2-5%), connectivity involving the power networks, which are associated with the power switches, may occupy valuable resources within transistor region 120. Thus, efficient utilization of resources for the power networks may provide additional area in transistor region 120 for other utilizations.

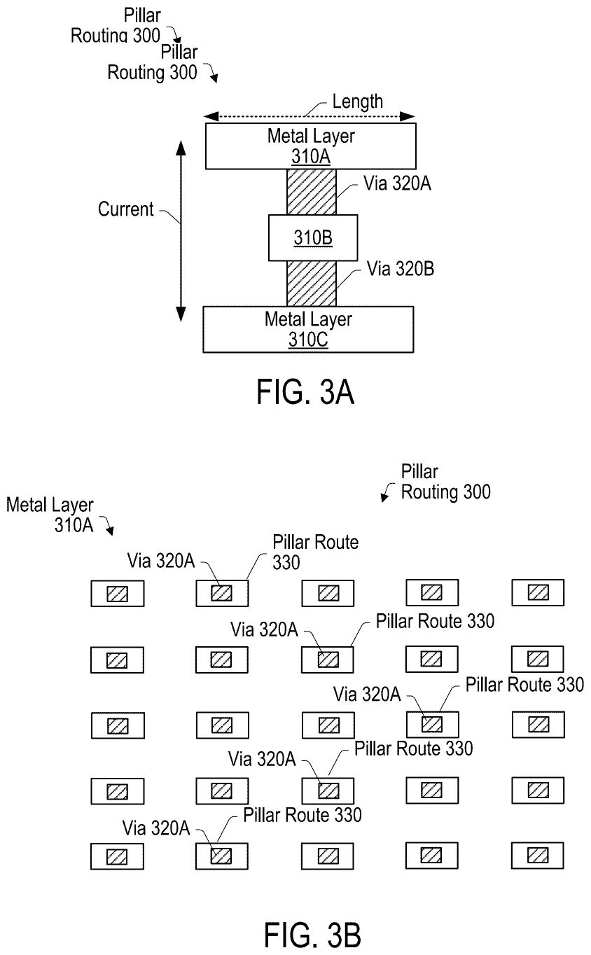

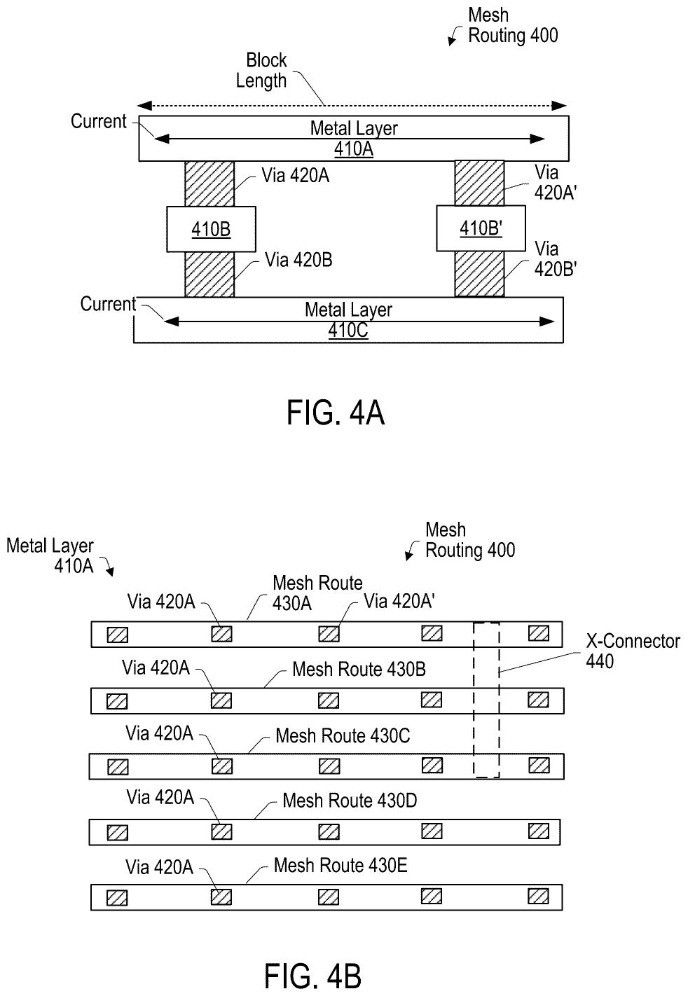

The present disclosure recognizes that various connectivity designs may be implemented to efficiently route power network resources through the transistor region of an integrated circuit device having power switches. In various embodiments, efficiently routing the power network resources involves selection of different types of routing in various metal layers associated with the routing. Examples of different types of routing utilized herein include pillar routing and mesh routing, which are described in detail below with reference to FIGS. 3A-4B.

Efficiently routing the power network resources through the transistor region may provide additional area for other resources in the transistor region. For instance, resources may be available for as additional routings (e.g., signal routings) or the placement of additional components or circuits. Adding capability for additional resources beyond power network resources may improve freedom and flexibility in the design of the VLSI device or improve the operational capacity of the VLSI device. The opened up capability may be utilized, for example, to increase the number of other types of transistors or circuit elements, allowing for more complex or powerful devices. In some instances, the design of integrated circuits may include more optimized routing strategies for signals in the devices with more efficient power network routing. Manufacturing may also be more efficient in certain instances with optimized design strategies.

Certain embodiments disclosed herein have three broad elements: 1) a transistor region with a core logic region and a power switch region; 2) three sets of one or more metal layers positioned above the transistor region for routing of power network resources to the core logic region or the power switch region, and 3) selection of various types of pillar routing and mesh routing in the sets of metal layers based on the power network and the destination of the routing in the power network.

In various embodiments directed to TVDD routing, TVDD routing for connections is provided to power switch region 140 only with no connections to core logic region 130 or functional circuit 150. In certain embodiments, for the power switch connections, the first set of metal layers (e.g., the set closest to the transistor region and the power switch) has pillar routing in the last metal layer furthest from the transistor region with the rest of the layers having mesh routing. In various embodiments, the TVDD routing includes combinations of mesh and pillar routing in the second and third sets of one or more metal layers above the first set of metal layers.

In various embodiments directed to VVDD routing, VVDD routing includes only the first set of metal layers (e.g., the set closest to the transistor region) and has connections to both power switch region 140 and core logic region 130 and functional circuits 150 in the core logic region. In certain embodiments, the first set of metal layers (e.g., the set closest to the transistor region and the power switch) has mesh routing in the last metal layer furthest from the transistor region where the mesh routing provides a connection between the routing above power switch region connected to the power switch and the routing above the core logic region connected to the functional circuits. In various embodiments, the VVDD routing above the power switch region includes only mesh routing while the VVDD routing above the core logic region includes some pillar routing.

In various embodiments directed to VSS routing, VSS routing has connections to both power switch region 140 and core logic region 130 and functional circuits 150 in the core logic region from the power supply source. In certain embodiments, a lowest metal layer in the second set of metal layers (e.g., the metal layer in the second set closest to the transistor region) and the last metal layer furthest from the transistor region both have mesh routing. In some embodiments, the second set of metal layers includes at least two metal layers with pillar routing between the lowest and last metal layers. The first set of metal layers may include mesh routing connected to the transistor region along with a combination of pillar and mesh routing or pillar only routing. In certain embodiments, the lowest metal layer in the third set of metal layers (furthest set from transistor region) includes mesh routing for distributing ground supply voltage.

As used herein, the term “pillar routing” refers to routing (e.g., metal structures) in a metal layer that primarily transfers current vertically through the metal layer. For instance, pillar routing may be structurally and functionally similar to a via through an insulating layer where the via transfers current vertically through the insulating layer. In some instances, pillar routing may be referred to as pillar pattern metallization or vertical routing.

FIG. 3A depicts a side-view representation of pillar routing, according to some embodiments. In the illustrated embodiment, pillar routing 300 is shown for each of metal layer 310A, metal layer 310B, and metal layer 310C. Vias 320A and 320B interconnect metal structures in the metal layers through intermediate insulating layers (not shown). As shown in FIG. 3A, current (solid line arrow) primarily transfers up or down between the pillar routes (e.g., metal structures) of metal layer 310A, metal layer 310B, and metal layer 310C.

In certain embodiments, metal structures in the metal layers with pillar routing (such as metal layer 310A, metal layer 310B, and metal layer 310C) have horizontal dimensions (e.g., length or width) that are designed to be, at most, a minimum amount necessary for landing a specified number (e.g., n) of vias going down or up from the pillar routing. For example, as shown in FIG. 3A, the metal structures in metal layer 310A and metal layer 310C may have lengths (dashed line arrow) that are a minimum needed to land four vias with the length of a via (e.g., length of via 320A or via 320B). Accordingly, metal layer 310A and metal layer 310C are designed to have metal structures with a maximum length of four via lengths. As another example, metal layer 310B may have metal structures with a length that is a minimum needed to land two vias and thus the metal layer is designed to have metal structures with a maximum length of two via lengths.

FIG. 3B depicts a top plan view representation of pillar routing, according to some embodiments. In the illustrated embodiment, a single metal layer (e.g., metal layer 310A) and a single layer of vias (e.g., vias 320) is shown. Metal layer 310A includes a layer of pillar routes 330 connected to a layer of vias 320A. Pillar routes 330 are metal structures that, as described above, have lengths dimensioned as minimum lengths for landing a specified number of vias routing above or below the metal structures. With the limited lengths of pillar routes 330, as shown, in FIG. 3B, the pillar routes will primarily transfer current up or down through metal layer 310A. For instance, one pillar route 330 transfers current up or down through vias (e.g., via 320A) connected to the pillar route. While FIG. 3B depicts a grid of pillar routes 330 and vias 320A, it should be understood that the layout of metal layer 310A may include any number of pillar routes placed in any arrangement depending on the desired design of pillar routing 300. For instance, as one example, some pillar routes 330 may be removed to provide more spacing between remaining pillar routes.

As used herein, the term “mesh routing” refers to routing (e.g., metal structures) in a metal layer that transfers current both vertically through the metal layer and across the metal layer over a wide distance horizontally (e.g., a wide horizontal area). Accordingly, mesh routing may transfer current over greater horizontal distances than vertical distance. For instance, while mesh routing transfer current vertically through the metal layer, mesh routing typically has much larger horizontal dimensions (e.g., length and width) than vertical dimensions (e.g., height). Thus, mesh routing transfers current more significantly (e.g., over longer distances) in the horizontal dimensions than in the vertical dimension. In some instances, mesh routing may be referred to as mesh pattern metallization or interconnect metallization. Generally speaking, mesh routing encompasses more resource utilization than pillar routing due to the wider distribution of metal over the horizontal dimensions.

FIG. 4A depicts a side-view representation of mesh routing, according to some embodiments. In the illustrated embodiment, mesh routing 400 is shown for metal layer 410A and metal layer 410C while metal layer 410B includes pillar routing. Vias 420A and 420B interconnect metal structures in the metal layers through intermediate insulating layers (not shown). As shown in FIG. 4A, current (solid line arrow) primarily transfers horizontally in the mesh routing metal layers—horizontally through metal structures in metal layer 410A and metal layer 410C. Vias 420A, 420B and metal layer 410B (e.g., pillar routing) provide vertical transfer of current between metal layer 410A and metal layer 410C.

In certain embodiments, mesh routing transfers current across a horizontal area that covers an area of a logic block or design block in a device. For instance, metal layer 410A may transfer current horizontally across an entire block length (dashed line arrow), as shown in FIG. 4A. Accordingly, metal layer 410A distributes current across the area of the entire block. Metal layer 410C may also distribute current across the area of the block. Thus, one possible current path in the illustrated embodiment of FIG. 4A may be, starting in on the left side of metal layer 410—across metal layer 410A′ to the right, down via 420A′, down metal layer 410B′, down via 420B′, across metal layer 410C to the left, up via 420B, up metal layer 410B (which is same metal layer as 410B′ but a separate pillar), and up via 420A back to metal layer 410A.

FIG. 4B depicts a top plan view representation of mesh routing, according to some embodiments. In the illustrated embodiment, a single metal layer (e.g., metal layer 410A) and a single layer of vias (e.g., vias 420A) is shown. Metal layer 410A includes a layer of mesh routes 430A-E connected to a layer of vias 420A. Mesh routes 430A-E are, for example, metal structures that have lengths approximately spanning dimensions of the logic block. It should be understood that mesh routing 400 may include any number of mesh routes in metal layer 410A. Additionally, some embodiments may be contemplated where one or more of mesh routes 430 are interconnected. For instance, cross-connector 440 (dashed line) may be placed between one or more mesh routes to interconnect the routes.

As shown in FIG. 4B, mesh routing 400 includes mesh routes 430 that primarily transfer current horizontally across the metal layer with any number of vias 420A connected to the mesh routes. As with mesh routes 430, the number and arrangement of vias 420A may vary depending on the design needs for mesh routing 400. For instance, the number of vias 420A connecting to a mesh route (e.g., mesh route 430A) may vary depending on the desired transfer of current vertically to/from metal layer 410A.

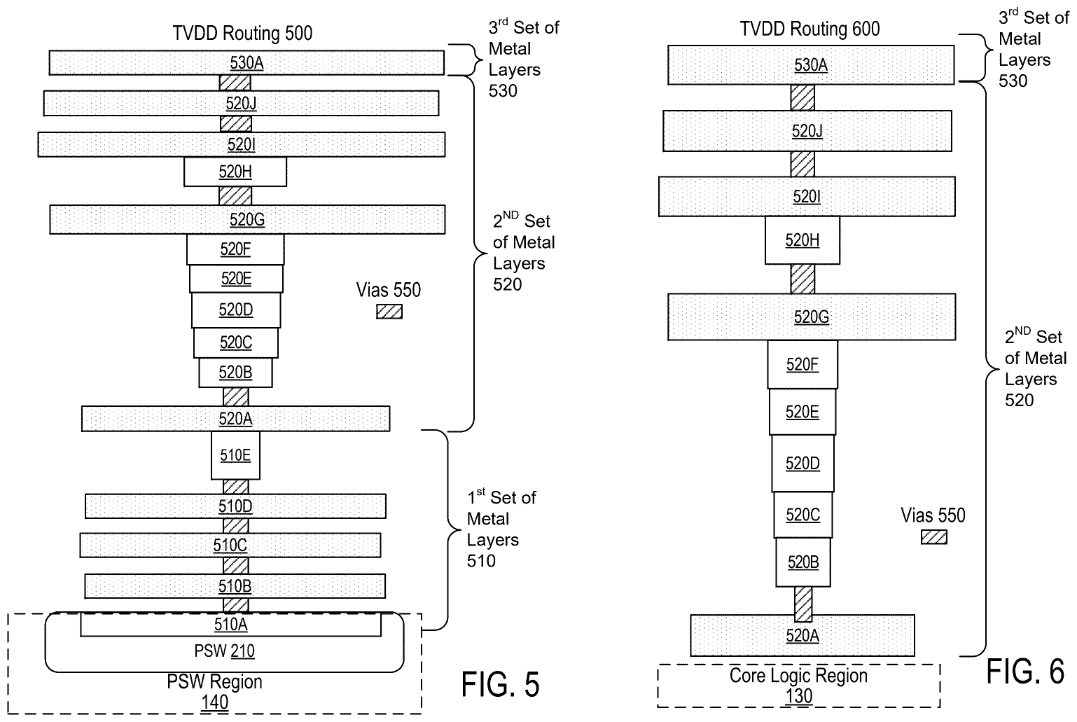

Various embodiments of routing of power network resources to a core logic region or a power switch region of a transistor region are now described with reference to FIGS. 5-16. The embodiments described herein generally reference routing through three different sets of one or more metal layers—a first set of one or more metal layers 510, a second set of one or more metal layers 520, and a third set of one or more metal layers 530. Unless otherwise explicitly indicated, it should be understood that the number of metal layers in each set—510, 520, 530—may vary. For instance, only a single metal layer (530A) is depicted for the third set of metal layers 530 but it should be understood that the third set of metal layers may include any number of additional metal layers.

Additionally, it should be understood that unless specifically indicated, pillar routing or mesh routing may be used interchangeably where appropriate in the disclosed embodiments. For instance, pillar routing or mesh routing may be used interchangeably in instances where neither routing is specifically called for in the disclosed embodiments. FIGS. 5-16 further include basic representations of vias 550 for interconnection through insulating layers (not shown). It should be understood that any number of vias between metal layers may be implemented as desired or available. For example, multiple vias 550 may be placed between metal layers with mesh routing to further interconnect the metal layers and improve electrical conductivity between the metal layers. Additionally, in some depictions, vias are not shown between metal layers with pillar routing for simplicity in the drawings. As one example, metal layer 510E, in FIG. 5, includes pillar routing where the via that would be vertically above the metal layer is included as part of the depiction of the metal layer.

FIG. 5 depicts a side-view representation of TVDD routing over a power switch region of a device, according to some embodiments. Note that in FIGS. 5-16, pillar routing in metal layers is indicated by the metal layer having no pattern while mesh routing in the metal layers is indicated by the metal layer having a dotted pattern. In the illustrated embodiment of FIG. 5, TVDD routing 500 includes routing between a power supply source and power switch 210 in power switch region 140. Routing to the power supply source may include, for example, additional metal layers above metal layer 530A in third set of metal layers 530. Connection to power switch 210 may be made by metal layer 510A. Metal layer 510A may include, for example, a pin or other connection terminal connecting via 550 above the metal layer to power switch 210. In some embodiments, metal layer 510A is a lowest metal layer in first set of metal layers 510 (e.g., a metal layer vertically closest to power switch region 140 in transistor region 120).

Going up from metal layer 510A, in various embodiments, TVDD routing 500 includes mesh routing in metal layers 510B, 510C, 510D. Then, in the last metal layer of first set of metal layers 510 furthest from power switch region 140 (e.g., metal layer 510E), pillar routing is implemented. Mesh routing may be used in the intermediate metal layers of first metal layers 510 (e.g., metal layers 510B, 510C, 510D) to provide high interconnectivity between the metal layers while pillar routing is used in the uppermost/last metal layer 510E of the first set of metal layers to provide specific contact to a first metal layer in the next set of metal layers—metal layer 520A in second set of metal layers 520.

In certain embodiments, the first metal layer in second set of metal layers 520 (e.g., metal layer 520A) uses mesh routing. Utilizing mesh routing in metal layer 520A interconnects TVDD routing 500 above power switch region 140 to TVDD routing 600 above core logic region 130 (shown in FIG. 6). FIG. 6 depicts a side-view representation of TVDD routing 600 over core logic region 130 of a device, according to some embodiments. Note that TVDD routing 600 is absent any routing in the first set of metal layers above core logic region 130. No routing is needed in this instance since TVDD is not connected to any structures (e.g., any functional circuits 150) in core logic region 130.

From metal layer 520A upwards to metal layer 530A, both TVDD routing 500 and TVDD routing 600, shown in FIGS. 5 and 6, may be substantially identical in structure, as described together herein. In certain embodiments, second set of metal layers 520 includes primarily pillar routing in metal layers. For instance, in the illustrated embodiment, metal layers 520B-F and 520H may be layers of pillar routing while metal layers 520G, 520I, 520J are layers of mesh routing. The use of primarily pillar routing in second set of metal layers 520 reduces the amount of routing resources in the second set of metal layers used for TVDD routing and enables additional space for other resources (e.g., signal routing or devices positioned in the topside metal layers).

The lowest metal layer, 530A, in third set of metal layers 530 may be mesh routing. Between the mesh routing in metal layer 530A and the mesh routing in any of the second set of metal layers—e.g., metal layers 520A, 520G, 520I, 520J, TVDD routing can be distributed between above core logic region 130 and power switch region 140 to allow increased TVDD capacity or lower resistance through higher metal usage.

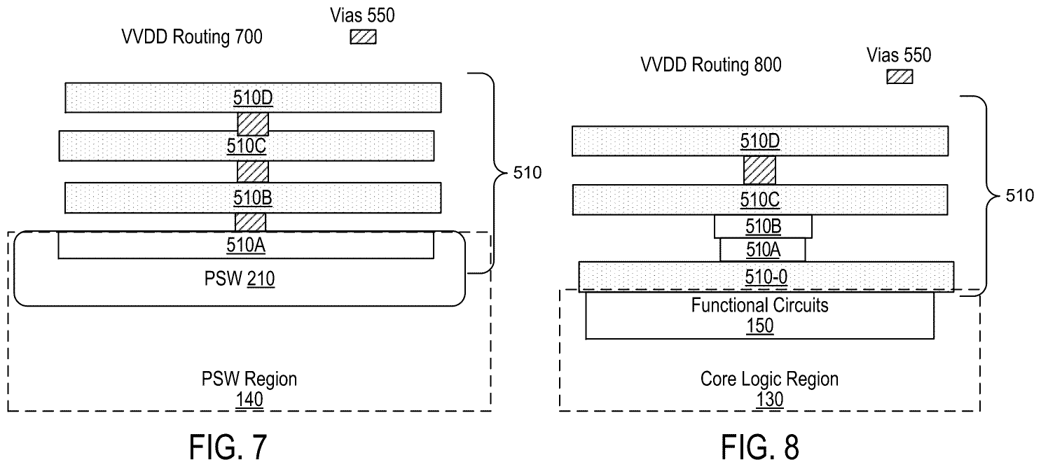

FIG. 7 depicts a side-view representation of VVDD routing over a power switch region of a device, according to some embodiments. FIG. 8 depicts a side-view representation of VVDD routing over a core logic region of a device, according to some embodiments. In various embodiments, VVDD routing 700, shown in FIG. 7, and VVDD routing 800, shown in FIG. 8, are limited to first set of metal layers 510 as the VVDD routing stays within the first set of metal layers for direct routing between power switch region 140 and core logic region 130. The direct routing provided in first set of metal layers 510 provides VVDD voltage directly from power switch 210 to functional circuits 150.

In certain embodiments, as shown in FIG. 7, VVDD routing 700 includes a connection to power switch 210 for VVDD made by metal layer 510A. Metal layer 510A may include, for example, a pin or other connection terminal connecting via 550 above the metal layer to power switch 210. Above metal layer 510A, VVDD routing 700 may include all or primarily mesh routing in metal layers 510B-510D with metal layer 510D being the uppermost metal layer in first set of metal layers (e.g., the furthest metal layer in the first set from transistor region 120).

Using mesh routing increases the capacity for VVDD routing 700 and allows transfer of VVDD to the metal layers above core logic region for VVDD routing 800 through the mesh routing. In certain embodiments, as shown in FIG. 8, VVDD routing 800 includes primarily mesh routing (e.g., metal layers 510-0, 510C, 510D) with some pillar routing in metal layers 510A, 510B. Metal layer 510-0 may be a connection layer to functional circuits 150 in core logic region 130 that provides distributed, high capacity connection for VVDD to the functional circuits. Pillar routing in metal layers 510A, 510B may thus provide directed connections to metal layer 510-0 while mesh routing in metal layers 510C, 510D provides connected mesh with the same metal layers in VVDD routing 700 above power switch region 140.

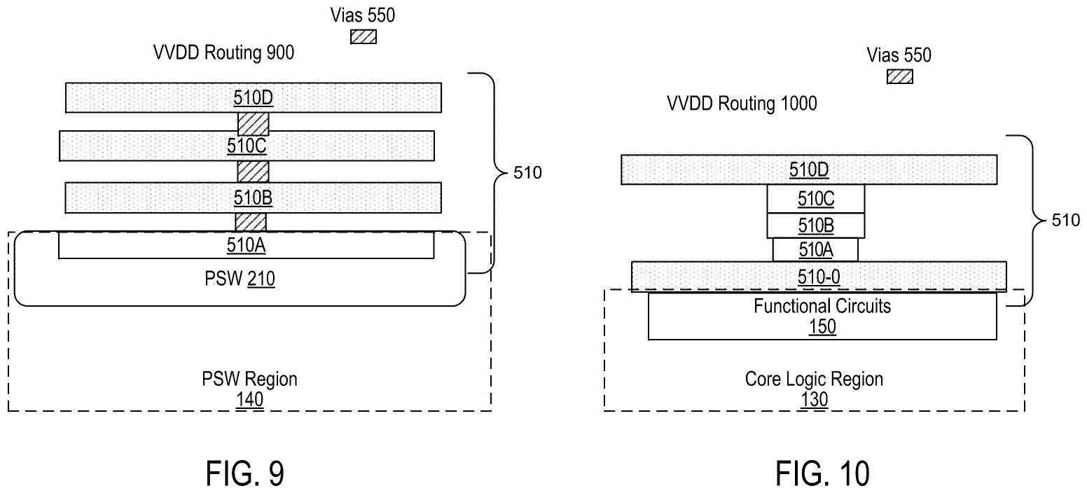

FIGS. 9 and 10 depict a possible alternative embodiment of VVDD routing. FIG. 9 depicts another side-view representation of VVDD routing over a power switch region of a device. FIG. 10 depicts another side-view representation of VVDD routing over a core logic region of a device, according to some embodiments. In certain embodiments, VVDD routing 900 above power switch region 140, shown in FIG. 9 is substantially similar to VVDD routing 700. VVDD routing 1000 above core logic region 130, shown in FIG. 10, may, however, have an increased amount of pillar routing compared to VVDD routing 800 with all pillar routing in metal layers 510A-C between the lowest metal layer 510-0 and the uppermost metal layer 510D. The use of more pillar routing may be implemented to allow more space for additional resources in first set of metal layers 510.

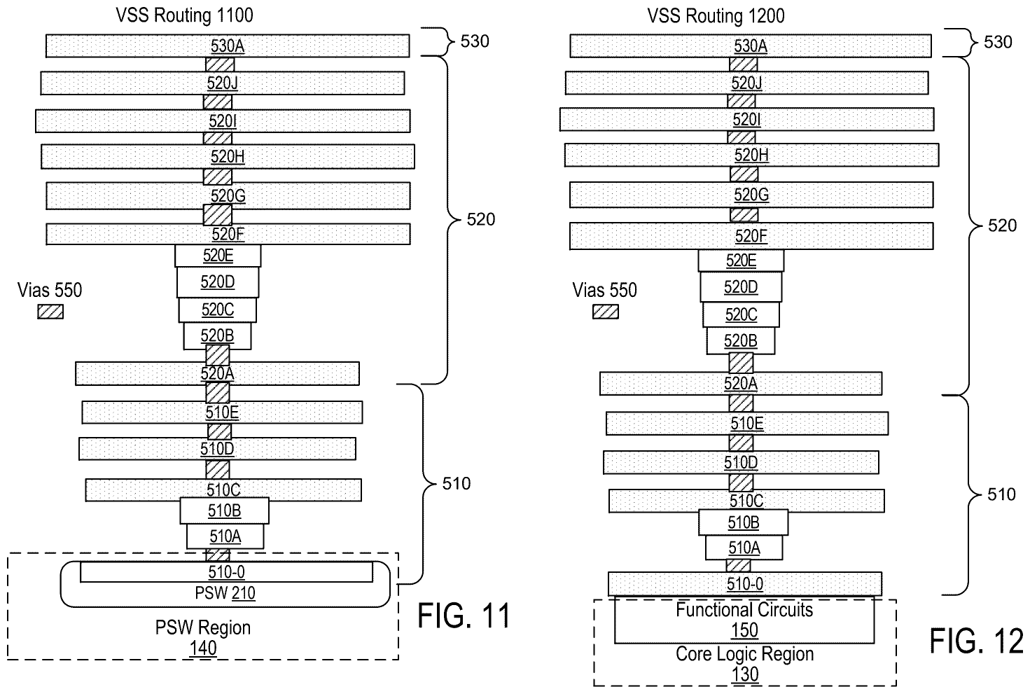

FIG. 11 depicts a side-view representation of VSS routing over a power switch region of a device, according to some embodiments. FIG. 12 depicts a side-view representation of VSS routing over a core logic region of a device, according to some embodiments. In various embodiments, VSS routing connects to both power switches 210 in power switch region 140 and functional circuits 150 in core logic region 130. In the illustrated embodiments of FIG. 11 and FIG. 12, third set of metal layers 530 and second set of metal layers 520 have substantially identical arrangements of mesh routing and pillar routing. For instance, metal layer 530A is mesh routing, metal layers 520F-J are mesh routing, metal layers 520B-E are pillar routing, and metal layer 520A is mesh routing. Additionally, first set of metal layers 510 in both VSS routing 1100 and VSS routing 1200 may be substantially identical to each other with metal layers 510C-510E being mesh routing and metal layers 510A-B being pillar routing. Metal layer 510-0 may be used for connections to power switch 210 or functional circuits 150, as described herein.

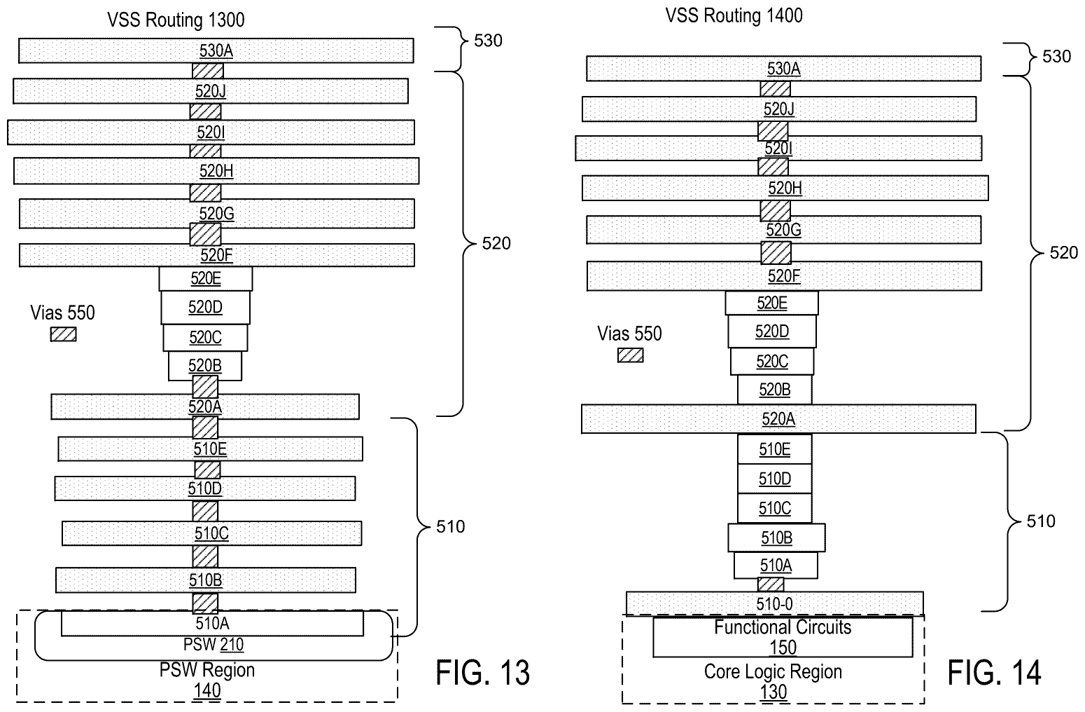

FIG. 13 depicts a side-view representation of an alternative embodiment of VSS routing over a power switch region of a device. In the illustrated embodiment, VSS routing 1300 has substantially all mesh routing in first set of metal layers 510 (e.g., metal layers 510B-510E are mesh routing) over power switch region 130 with metal layer 510A being a connection layer that may include mesh routing or other types of connection.

FIG. 14 depicts a side-view representation of an alternative embodiment of VSS routing over a core logic region of a device. In some embodiments, VSS routing 1400 has primarily pillar routing in first set of metal layers 510 (e.g., metal layers 510A-510E are pillar routing). Metal layer 510-0 is a connection layer to functional circuits 150. The use of primarily pillar routing increases space for additional resources, as described herein.

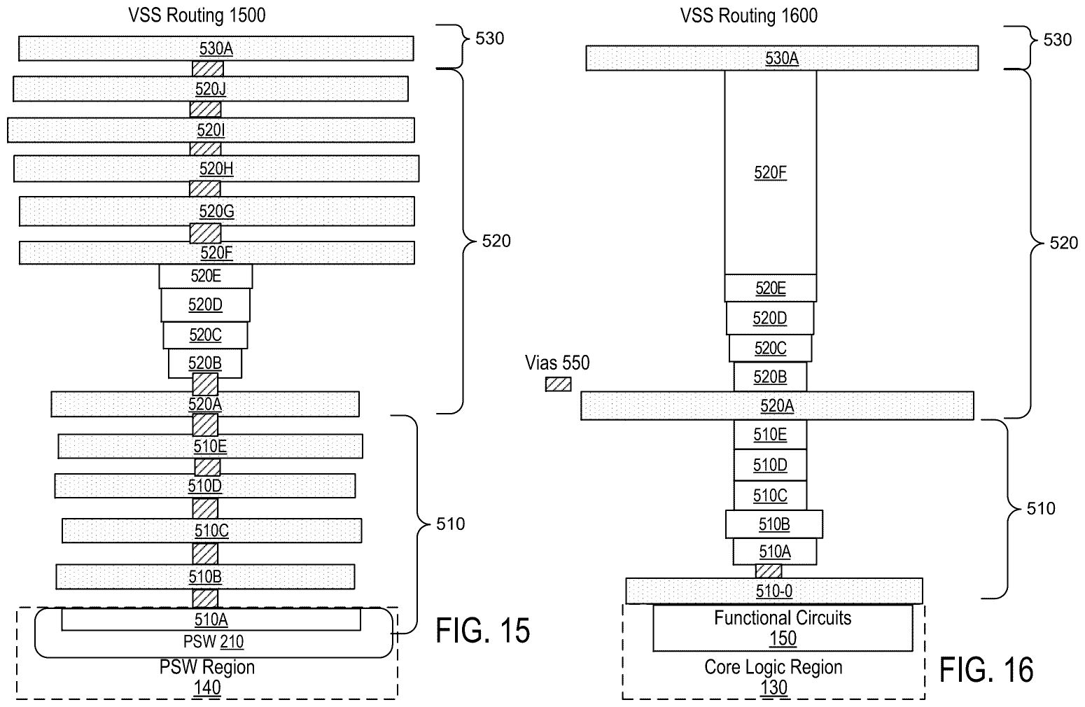

FIGS. 15 and 16 depict a possible alternative embodiment of VSS routing. FIG. 15 depicts a side-view representation of VSS routing 1500 over a power switch region of a device that is substantially similar to VSS routing 1300 in FIG. 13. FIG. 16 depicts a side-view representation of another alternative embodiment of VSS routing over a core logic region of a device. In the illustrated embodiment, VSS routing 1600 is primarily pillar routing in second set of metal layers 520 with metal layer 520A being mesh routing and remaining metal layers 520B-520F being pillar routing. First set of metal layers 510 is also primarily pillar routing (similar to VSS routing 1400, shown in FIG. 14). Accordingly, VSS routing 1600 includes more pillar routing and further increased space for other resources in the topside metal layers.

### Example Manufacturing Methods

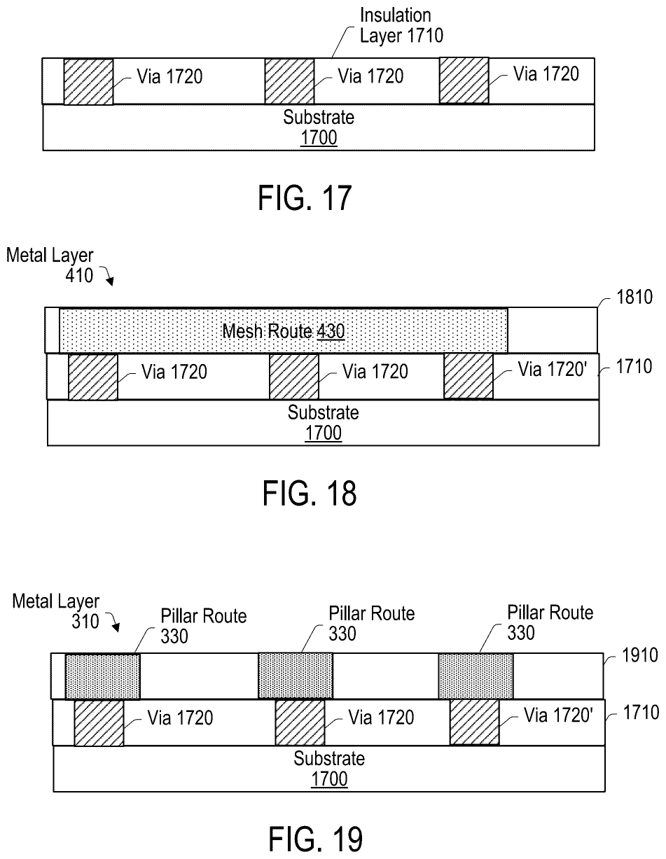

FIGS. 17-25 depict cross-sectional side-view representations of various possible steps in an exemplary embodiment of a method for manufacturing the various routing structures with mesh routings and pillar routings shown in FIGS. 5-16. Note that FIGS. 17-25 are shown along cross-sectional views similar to FIGS. 3A and 4A for showing results of manufacturing (e.g., process) steps to form various embodiments of mesh routing and pillar routing. For instance, the cross-sectional side-view representations in FIGS. 17-25 illustrate possible structural results of manufacturing steps for forming mesh routing on a substrate, pillar routing on a substrate, mesh routing on mesh routing, mesh routing on pillar routing, pillar routing on mesh routing, and pillar routing on pillar routing. The various routing structures depicted in FIGS. 5-16 may be constructed based on the principals of the individual manufacturing steps for mesh routings and pillar routings shown in FIGS. 17-25. Furthermore, it is noted that FIGS. 17-25 depict cross-sectional side-view representations of intermediate structural results (e.g., structural end results for mesh routing or pillar routing layers in a layer-by-layer manufacturing process) of manufacturing steps involved in forming the full routing structures described herein.

In various embodiments, one or more semiconductor manufacturing processing steps are implemented to form the intermediate structural results or structural end results depicted in FIGS. 17-25. Examples of semiconductor manufacturing processing steps include, but are not limited to, wafer fabrication, etching (e.g., material removal), photolithography processing, deposition (e.g., material deposition), planarization (e.g., chemical mechanical planarization), ion implantation (e.g., doping), packaging, and packaging test (e.g., end product testing). Etching may include any of various etching techniques such as, but not limited to, wet etching, dry etching, plasma etching, and laser etching. Photolithography processing may include steps for mask deposition, irradiation (e.g., patterning), pattern transfer (including any related etching, deposition, or ion implantation steps), and mask removal (if necessary). Material deposition may include deposition processes such as, but not limited to, physical deposition, chemical deposition, chemical vapor deposition, evaporation, diffusion, spin coating, and electron beam deposition.

Any of the various semiconductor manufacturing processing steps mentioned above along with any related semiconductor manufacturing processing steps not explicitly disclosed may be implemented to arrive at the structures depicted in FIGS. 17-25 with the understanding that those skilled in the art would be able to determine a set of appropriate semiconductor manufacturing processing steps for implementing the depicted structures based on the present disclosure. Additionally, at some points throughout the present disclosure, semiconductor manufacturing processing steps may be explicitly recited in relation to specific structures. In such instances, it is understood that variations beyond the explicitly recited semiconductor manufacturing processing steps may be possible as known to those skilled in the art. Thus, while FIGS. 17-25 depict one exemplary embodiment for step-by-step manufacturing of devices described herein, additional embodiments for manufacturing devices described herein may be contemplated with modifications or alternatives that fall within the spirit or scope of the present disclosure where such modification or alternatives may include variations on the disclosed semiconductor manufacturing processing steps.

FIG. 17 is a cross-sectional side-view representation of a beginning manufacturing step for forming routing on a substrate, according to some embodiments. In the illustrated embodiment, substrate 1700 may be any substrate on which the routing structures described herein may be formed. Examples include, but are not limited to, a semiconductor substrate, a metal connection layer (e.g., a metal layer connecting to circuits such as metal layer 510-0, described herein), a layer of terminals connecting to circuits, and a dielectric layer.

In certain embodiments, insulation layer 1710 is formed on substrate 1700. Insulation layer 1710 may be, for example, a dielectric layer or other electrically insulating layer formed on substrate 1700. As shown in FIG. 17, manufacturing/processing to form routing on substrate 1700 may begin with forming vias 1720 through insulation layer 1710. Vias 1720 may be formed, for example, by forming openings in insulation 1710 and filling the openings with material (e.g., electrically conductive material) for the vias.

FIG. 18 is a cross-sectional side-view representation of a manufacturing step for forming mesh routing on a substrate, according to some embodiments. In the illustrated embodiment, metal layer 410 is formed on insulation layer 1710. Metal layer 410 includes mesh route 430. In certain embodiments, mesh route 430 is a metal structure that has at least one horizontal dimension (e.g., length) that spans a corresponding horizontal dimension (e.g., length) of a logic block and couples to multiple vias 1720 across its length. For instance, as shown in FIG. 18, the logic block may span between via 1720 and via 1720′ and mesh route 430 correspondingly spans across both the vias.

In various embodiments, mesh route 430 is enclosed (e.g., encapsulated) in insulation layer 1810. Insulation layer 1810 may be a dielectric layer or other electrically insulating layer. In some embodiments, insulation layer 1810 is formed first and then mesh route 430 is formed in the insulation layer by forming openings in the insulation layer and then depositing metal in the openings. In some embodiments, mesh route 430 (and metal layer 410) is formed first and then insulation layer 1810 is formed around (e.g., formed to encapsulate) the mesh route.

FIG. 19 is a cross-sectional side-view representation of a manufacturing step for forming pillar routing on a substrate, according to some embodiments. In the illustrated embodiment, metal layer 310 is formed on insulation layer 1710. Metal layer 310 includes pillar routes 330. In certain embodiments, pillar routes 330 are metal structures that have horizontal dimensions (e.g., length or width) that are designed to be, at most, a minimum amount necessary for landing a specified number of vias going down or up from the pillar routes. For instance, as shown in FIG. 19, pillar routes 330 have lengths designed to be a minimum amount for landing multiple vias 1720.

In various embodiments, pillar routes 330 are enclosed in insulation layer 1910. Insulation layer 1910 may be a dielectric layer or other electrically insulating layer. In some embodiments, insulation layer 1910 is formed first and then pillar routes 330 are formed in the insulation layer by forming openings in the insulation layer and then depositing metal in the openings. In some embodiments, pillar routes 330 (and metal layer 310) are formed first and then insulation layer 1910 is formed around (e.g., formed to encapsulate) the pillar routes.

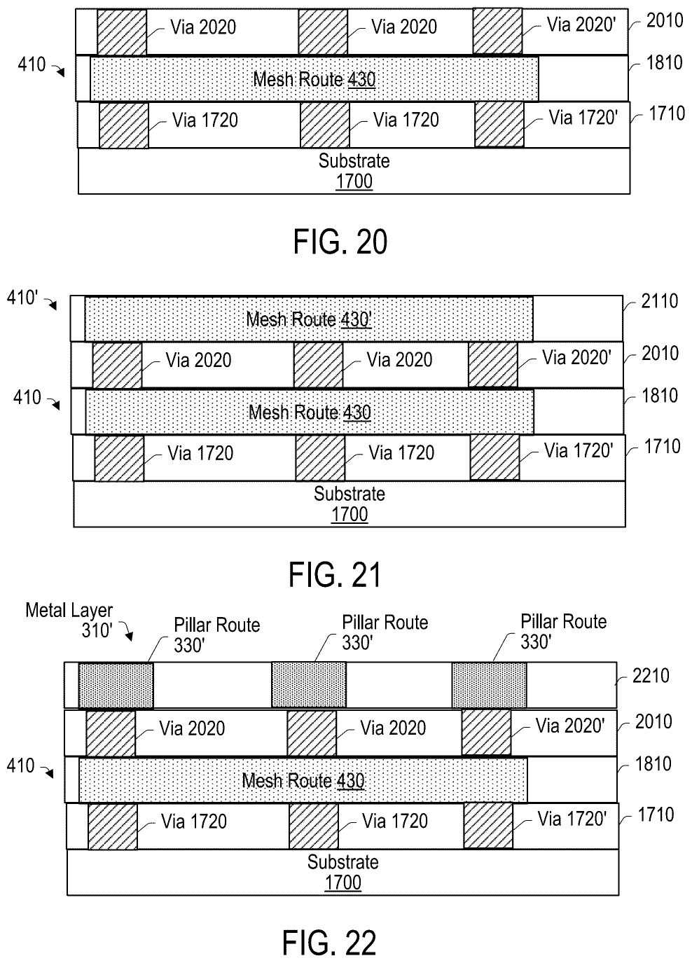

FIG. 20 is a cross-sectional side-view representation of a manufacturing step for forming vias on mesh routing, according to some embodiments. In the illustrated embodiment, insulation layer 2010 with vias 2020 is formed on mesh route 430 and metal layer 410. In certain embodiments, insulation layer 2010 is formed on metal layer 410 first and then vias 2020 are formed in the insulation layer by forming openings and depositing via material (e.g., electrically conductive material) in the openings. In some embodiments, as shown in FIG. 20, vias 2020 are aligned with vias 1720 in the underlying insulation layer 1710. Additional embodiments may be contemplated where vias 2020 are not aligned with vias 1720.

With insulation layer 2010 and vias 2020 formed on metal layer 410 and mesh route 430 (e.g., mesh routing), embodiments may be contemplated where either additional mesh routing is formed on the insulation layer and vias above the mesh routing or pillar routing is formed on the insulation layer and vias above the mesh routing. FIG. 21 is a cross-sectional side-view representation of a manufacturing step for forming mesh routing on mesh routing, according to some embodiments. In the illustrated embodiment, mesh route 430′ of metal layer 410′ and insulation layer 2110 are formed on the structure shown in FIG. 20.

In various embodiments, mesh route 430′ is enclosed by insulation layer 2110, which may be a dielectric layer or other electrically insulating layer. In some embodiments, insulation layer 2110 is formed first and then mesh route 430′ is formed in the insulation layer as described herein. In some embodiments, mesh route 430′ (and metal layer 410′) is formed first and then insulation layer 2110 encapsulates the mesh route. In various embodiments, multiple vias 2020 connect mesh route 430 to mesh route 430′, which distributes current transfer over a wide distance horizontally between both metal layer 410 and metal layer 410′.

FIG. 22 is a cross-sectional side-view representation of a manufacturing step for forming pillar routing on mesh routing, according to some embodiments. In the illustrated embodiment, pillar routes 330′ of metal layer 310′ and insulation layer 2210 are formed on the structure shown in FIG. 20. In various embodiments, pillar routes 330′ are enclosed by insulation layer 2210, which may be a dielectric layer or other electrically insulating layer. In some embodiments, insulation layer 2210 is formed first and then pillar routes 330′ are formed in the insulation layer as described herein. In some embodiments, pillar routes 330′ (and metal layer 310′) are formed first and then insulation layer 2210 encapsulates the pillar routes. In certain embodiments, pillar routes 330′ are aligned with vias 2020 in the underlying layer. Pillar routes 330′ and vias 2020 may be aligned to provide substantially vertical current transfer through insulation layers 2010 and 2210 from the underlying mesh route 430.

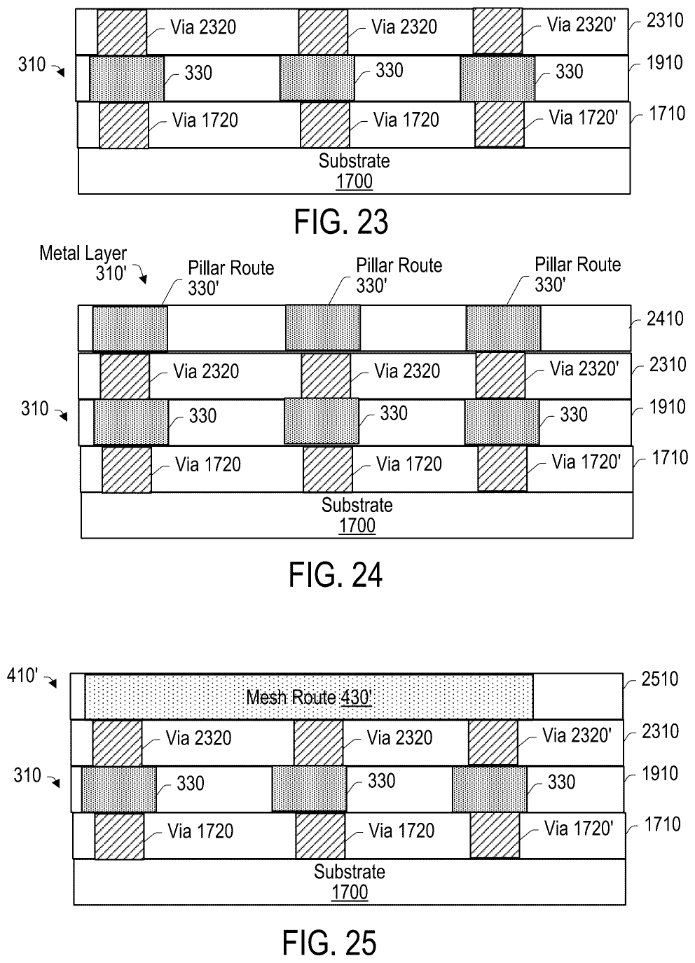

FIG. 23 is a cross-sectional side-view representation of a manufacturing step for forming vias on pillar routing, according to some embodiments. In the illustrated embodiment, insulation layer 2310 with vias 2320 is formed on pillar routes 330 and metal layer 310. In certain embodiments, vias 2320 are aligned with pillar routes 330. Alignment between vias 2320 and pillar routes 330 maintains electrical contiguity between metal layer 310 and any metal layer formed above insulation layer 2310.

In certain embodiments, insulation layer 2310 is formed on metal layer 310 first and then vias 2320 are formed in the insulation layer by forming openings and depositing via material (e.g., electrically conductive material) in the openings. With insulation layer 2310 and vias 2320 formed on metal layer 310 and pillar routes 330 (e.g., the pillar routing), embodiments may be contemplated where either additional pillar routing is formed on the insulation layer and vias above the pillar routing or mesh routing is formed on the insulation layer and vias above the pillar routing.

FIG. 24 is a cross-sectional side-view representation of a manufacturing step for forming pillar routing on pillar routing, according to some embodiments. In the illustrated embodiment, pillar routes 330′ of metal layer 310′ and insulation layer 2410 are formed on the structure shown in FIG. 23. In various embodiments, pillar routes 330′ are enclosed by insulation layer 2410, which may be a dielectric layer or other electrically insulating layer. In some embodiments, insulation layer 2410 is formed first and then pillar routes 330′ are formed in the insulation layer as described herein. In some embodiments, pillar routes 330′ (and metal layer 310′) are formed first and then insulation layer 2410 encapsulates the pillar routes. In certain embodiments, pillar routes 330′ are aligned with vias 2320 in the underlying layer. Accordingly, pillar routes 330′ are aligned with pillar routes 330 and the structure may provide substantially vertical current transfer through the various insulation layers (e.g., through insulation layers 1710, 1910, 2310, and 2410).

FIG. 25 is a cross-sectional side-view representation of a manufacturing step for forming mesh routing on pillar routing, according to some embodiments. In the illustrated embodiment, mesh route 430′ of metal layer 410′ and insulation layer 2510 are formed on the structure shown in FIG. 23. In various embodiments, mesh route 430′ is enclosed by insulation layer 2510, which may be a dielectric layer or other electrically insulating layer. In some embodiments, insulation layer 2510 is formed first and then mesh route 430′ is formed in the insulation layer as described herein. In some embodiments, mesh route 430′ (and metal layer 410′) is formed first and then insulation layer 2510 encapsulates the mesh route. In various embodiments, mesh route 430′ connects to multiple vias 2320, which are connected to individual pillar routes 330. Accordingly, mesh route 430′ may electrically connect together the individual pillar routes 330 in metal layer 310 and distribute current transfer over a wide distance horizontally in metal layer 410′. Embodiments may be contemplated, however, where one or more of vias 2320 are removed to inhibit electrical connection between pillar routes 330 by mesh route 430′.

Note that similar steps for forming any of the mesh routing, pillar routing, or via structures described herein may be implemented based on the illustrated steps shown in FIGS. 17-26. Further, it should be noted that these steps may also form the basis of any process for forming a routing structure that has various combinations of mesh routing and pillar routing. For instance, the steps described may form the basis for forming any of the disclosed TVDD routings 500 (shown in FIGS. 5-6), VVDD routings 700/900/1000 (shown in FIGS. 7-10), or VSS routings 1100/1200/1300/1400/1500/1600 (shown in FIGS. 11-16).

### Example Computer System

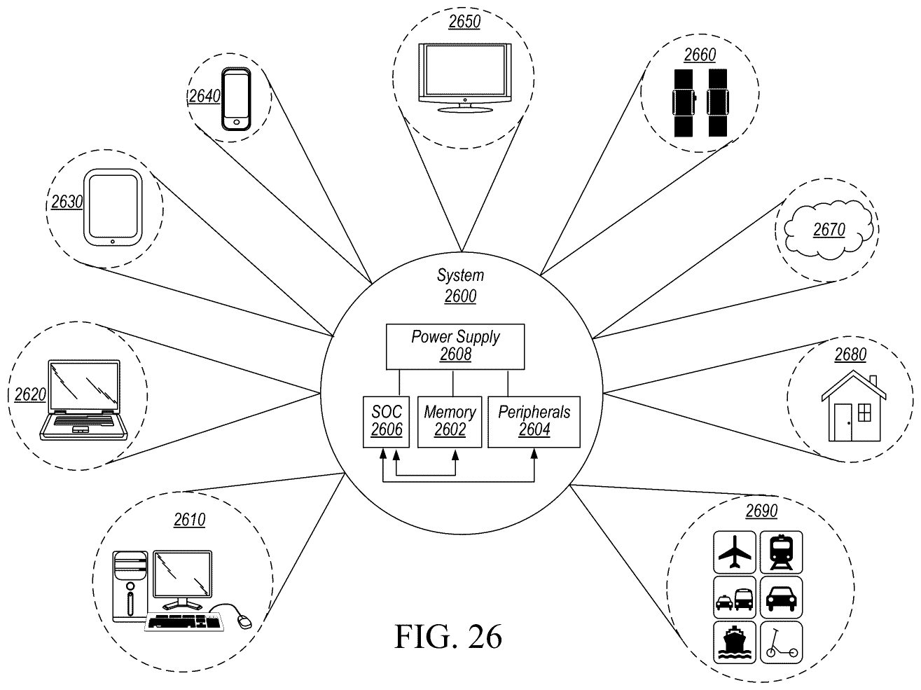

Turning next to FIG. 26, a block diagram of one embodiment of a system 2600 is shown that may incorporate and/or otherwise utilize the methods and mechanisms described herein. In the illustrated embodiment, the system 2600 includes at least one instance of a system on chip (SoC) 2606 which may include multiple types of processing units, such as a central processing unit (CPU), a graphics processing unit (GPU), or otherwise, a communication fabric, and interfaces to memories and input/output devices. In some embodiments, one or more processors in SoC 2606 includes multiple execution lanes and an instruction issue queue. In various embodiments, SoC 2606 is coupled to external memory 2602, peripherals 2604, and power supply 2608.

A power supply 2608 is also provided which supplies the supply voltages to SoC 2606 as well as one or more supply voltages to the memory 2602 and/or the peripherals 2604. In various embodiments, power supply 2608 represents a battery (e.g., a rechargeable battery in a smart phone, laptop or tablet computer, or other device). In some embodiments, more than one instance of SoC 2606 is included (and more than one external memory 2602 is included as well).

The memory 2602 is any type of memory, such as dynamic random access memory (DRAM), synchronous DRAM (SDRAM), double data rate (DDR, DDR2, DDR3, etc.) SDRAM (including mobile versions of the SDRAMs such as mDDR3, etc., and/or low power versions of the SDRAMs such as LPDDR2, etc.), RAMBUS DRAM (RDRAM), static RAM (SRAM), etc. One or more memory devices are coupled onto a circuit board to form memory modules such as single inline memory modules (SIMMs), dual inline memory modules (DIMMs), etc. Alternatively, the devices are mounted with a SoC or an integrated circuit in a chip-on-chip configuration, a package-on-package configuration, or a multi-chip module configuration.

The peripherals 2604 include any desired circuitry, depending on the type of system 2600. For example, in one embodiment, peripherals 2604 includes devices for various types of wireless communication, such as Wi-Fi, Bluetooth, cellular, global positioning system, etc. In some embodiments, the peripherals 2604 also include additional storage, including RAM storage, solid state storage, or disk storage. The peripherals 2604 include user interface devices such as a display screen, including touch display screens or multitouch display screens, keyboard or other input devices, microphones, speakers, etc.

As illustrated, system 2600 is shown to have application in a wide range of areas. For example, system 2600 may be utilized as part of the chips, circuitry, components, etc., of a desktop computer 2610, laptop computer 2620, tablet computer 2630, cellular or mobile phone 2640, or television 2650 (or set-top box coupled to a television). Also illustrated is a smartwatch and health monitoring device 2660. In some embodiments, smartwatch may include a variety of general-purpose computing related functions. For example, smartwatch may provide access to email, cellphone service, a user calendar, and so on. In various embodiments, a health monitoring device may be a dedicated medical device or otherwise include dedicated health related functionality. For example, a health monitoring device may monitor a user's vital signs, track proximity of a user to other users for the purpose of epidemiological social distancing, contact tracing, provide communication to an emergency service in the event of a health crisis, and so on. In various embodiments, the above-mentioned smartwatch may or may not include some or any health monitoring related functions. Other wearable devices are contemplated as well, such as devices worn around the neck, devices that are implantable in the human body, glasses designed to provide an augmented and/or virtual reality experience, and so on.

System 2600 may further be used as part of a cloud-based service(s) 2670. For example, the previously mentioned devices, and/or other devices, may access computing resources in the cloud (i.e., remotely located hardware and/or software resources). Still further, system 2600 may be utilized in one or more devices of a home 2680 other than those previously mentioned. For example, appliances within the home may monitor and detect conditions that warrant attention. For example, various devices within the home (e.g., a refrigerator, a cooling system, etc.) may monitor the status of the device and provide an alert to the homeowner (or, for example, a repair facility) should a particular event be detected. Alternatively, a thermostat may monitor the temperature in the home and may automate adjustments to a heating/cooling system based on a history of responses to various conditions by the homeowner. Also illustrated in FIG. 26 is the application of system 2600 to various modes of transportation 2690. For example, system 2600 may be used in the control and/or entertainment systems of aircraft, trains, buses, cars for hire, private automobiles, waterborne vessels from private boats to cruise liners, scooters (for rent or owned), and so on. In various cases, system 2600 may be used to provide automated guidance (e.g., self-driving vehicles), general systems control, and otherwise. These any many other embodiments are possible and are contemplated. It is noted that the devices and applications illustrated in FIG. 26 are illustrative only and are not intended to be limiting. Other devices are possible and are contemplated.

The present disclosure includes references to “an “embodiment” or groups of “embodiments” (e.g., “some embodiments” or “various embodiments”). Embodiments are different implementations or instances of the disclosed concepts. References to “an embodiment,” “one embodiment,” “a particular embodiment,” and the like do not necessarily refer to the same embodiment. A large number of possible embodiments are contemplated, including those specifically disclosed, as well as modifications or alternatives that fall within the spirit or scope of the disclosure.

This disclosure may discuss potential advantages that may arise from the disclosed embodiments. Not all implementations of these embodiments will necessarily manifest any or all of the potential advantages. Whether an advantage is realized for a particular implementation depends on many factors, some of which are outside the scope of this disclosure. In fact, there are a number of reasons why an implementation that falls within the scope of the claims might not exhibit some or all of any disclosed advantages. For example, a particular implementation might include other circuitry outside the scope of the disclosure that, in conjunction with one of the disclosed embodiments, negates or diminishes one or more the disclosed advantages. Furthermore, suboptimal design execution of a particular implementation (e.g., implementation techniques or tools) could also negate or diminish disclosed advantages. Even assuming a skilled implementation, realization of advantages may still depend upon other factors such as the environmental circumstances in which the implementation is deployed. For example, inputs supplied to a particular implementation may prevent one or more problems addressed in this disclosure from arising on a particular occasion, with the result that the benefit of its solution may not be realized. Given the existence of possible factors external to this disclosure, it is expressly intended that any potential advantages described herein are not to be construed as claim limitations that must be met to demonstrate infringement. Rather, identification of such potential advantages is intended to illustrate the type(s) of improvement available to designers having the benefit of this disclosure. That such advantages are described permissively (e.g., stating that a particular advantage “may arise”) is not intended to convey doubt about whether such advantages can in fact be realized, but rather to recognize the technical reality that realization of such advantages often depends on additional factors.

Unless stated otherwise, embodiments are non-limiting. That is, the disclosed embodiments are not intended to limit the scope of claims that are drafted based on this disclosure, even where only a single example is described with respect to a particular feature. The disclosed embodiments are intended to be illustrative rather than restrictive, absent any statements in the disclosure to the contrary. The application is thus intended to permit claims covering disclosed embodiments, as well as such alternatives, modifications, and equivalents that would be apparent to a person skilled in the art having the benefit of this disclosure.

For example, features in this application may be combined in any suitable manner. Accordingly, new claims may be formulated during prosecution of this application (or an application claiming priority thereto) to any such combination of features. In particular, with reference to the appended claims, features from dependent claims may be combined with those of other dependent claims where appropriate, including claims that depend from other independent claims. Similarly, features from respective independent claims may be combined where appropriate.

Accordingly, while the appended dependent claims may be drafted such that each depends on a single other claim, additional dependencies are also contemplated. Any combinations of features in the dependent that are consistent with this disclosure are contemplated and may be claimed in this or another application. In short, combinations are not limited to those specifically enumerated in the appended claims.

Where appropriate, it is also contemplated that claims drafted in one format or statutory type (e.g., apparatus) are intended to support corresponding claims of another format or statutory type (e.g., method).

Because this disclosure is a legal document, various terms and phrases may be subject to administrative and judicial interpretation. Public notice is hereby given that the following paragraphs, as well as definitions provided throughout the disclosure, are to be used in determining how to interpret claims that are drafted based on this disclosure.

References to a singular form of an item (i.e., a noun or noun phrase preceded by “a,” “an,” or “the”) are, unless context clearly dictates otherwise, intended to mean “one or more.” Reference to “an item” in a claim thus does not, without accompanying context, preclude additional instances of the item. A “plurality” of items refers to a set of two or more of the items.

The word “may” is used herein in a permissive sense (i.e., having the potential to, being able to) and not in a mandatory sense (i.e., must).

The terms “comprising” and “including,” and forms thereof, are open-ended and mean “including, but not limited to.”

When the term “or” is used in this disclosure with respect to a list of options, it will generally be understood to be used in the inclusive sense unless the context provides otherwise. Thus, a recitation of “x or y” is equivalent to “x or y, or both,” and thus covers 1) x but not y, 2) y but not x, and 3) both x and y. On the other hand, a phrase such as “either x or y, but not both” makes clear that “or” is being used in the exclusive sense.

A recitation of “w, x, y, or z, or any combination thereof” or “at least one of . . . w, x, y, and z” is intended to cover all possibilities involving a single element up to the total number of elements in the set. For example, given the set [w, x, y, z], these phrasings cover any single element of the set (e.g., w but not x, y, or z), any two elements (e.g., w and x, but not y or z), any three elements (e.g., w, x, and y, but not z), and all four elements. The phrase “at least one of ... w, x, y, and z” thus refers to at least one element of the set [w, x, y, z], thereby covering all possible combinations in this list of elements. This phrase is not to be interpreted to require that there is at least one instance of w, at least one instance of x, at least one instance of y, and at least one instance of z.

Various “labels” may precede nouns or noun phrases in this disclosure. Unless context provides otherwise, different labels used for a feature (e.g., “first circuit,” “second circuit,” “particular circuit,” “given circuit,” etc.) refer to different instances of the feature. Additionally, the labels “first,” “second,” and “third” when applied to a feature do not imply any type of ordering (e.g., spatial, temporal, logical, etc.), unless stated otherwise.

The phrase “based on” is used to describe one or more factors that affect a determination. This term does not foreclose the possibility that additional factors may affect the determination. That is, a determination may be solely based on specified factors or based on the specified factors as well as other, unspecified factors. Consider the phrase “determine A based on B.” This phrase specifies that B is a factor that is used to determine A or that affects the determination of A. This phrase does not foreclose that the determination of A may also be based on some other factor, such as C. This phrase is also intended to cover an embodiment in which A is determined based solely on B. As used herein, the phrase “based on” is synonymous with the phrase “based at least in part on.”

The phrases “in response to” and “responsive to” describe one or more factors that trigger an effect. This phrase does not foreclose the possibility that additional factors may affect or otherwise trigger the effect, either jointly with the specified factors or independent from the specified factors. That is, an effect may be solely in response to those factors, or may be in response to the specified factors as well as other, unspecified factors. Consider the phrase “perform A in response to B.” This phrase specifies that B is a factor that triggers the performance of A, or that triggers a particular result for A. This phrase does not foreclose that performing A may also be in response to some other factor, such as C. This phrase also does not foreclose that performing A may be jointly in response to B and C. This phrase is also intended to cover an embodiment in which A is performed solely in response to B. As used herein, the phrase “responsive to” is synonymous with the phrase “responsive at least in part to.” Similarly, the phrase “in response to” is synonymous with the phrase “at least in part in response to.”

Within this disclosure, different entities (which may variously be referred to as “units,” “circuits,” other components, etc.) may be described or claimed as “configured” to perform one or more tasks or operations. This formulation—[entity] configured to [perform one or more tasks]—is used herein to refer to structure (i.e., something physical). More specifically, this formulation is used to indicate that this structure is arranged to perform the one or more tasks during operation. A structure can be said to be “configured to” perform some task even if the structure is not currently being operated. Thus, an entity described or recited as being “configured to” perform some task refers to something physical, such as a device, circuit, a system having a processor unit and a memory storing program instructions executable to implement the task, etc. This phrase is not used herein to refer to something intangible.

In some cases, various units/circuits/components may be described herein as performing a set of task or operations. It is understood that those entities are “configured to” perform those tasks/operations, even if not specifically noted.

The term “configured to” is not intended to mean “configurable to.” An unprogrammed FPGA, for example, would not be considered to be “configured to” perform a particular function. This unprogrammed FPGA may be “configurable to” perform that function, however. After appropriate programming, the FPGA may then be said to be “configured to” perform the particular function.

For purposes of United States patent applications based on this disclosure, reciting in a claim that a structure is “configured to” perform one or more tasks is expressly intended not to invoke 35 U.S.C. § 112(f) for that claim element. Should Applicant wish to invoke Section 112(f) during prosecution of a United States patent application based on this disclosure, it will recite claim elements using the “means for” [performing a function] construct.

Different “circuits” may be described in this disclosure. These circuits or “circuitry” constitute hardware that includes various types of circuit elements, such as combinatorial logic, clocked storage devices (e.g., flip-flops, registers, latches, etc.), finite state machines, memory (e.g., random-access memory, embedded dynamic random-access memory), programmable logic arrays, and so on. Circuitry may be custom designed, or taken from standard libraries. In various implementations, circuitry can, as appropriate, include digital components, analog components, or a combination of both. Certain types of circuits may be commonly referred to as “units” (e.g., a decode unit, an arithmetic logic unit (ALU), functional unit, memory management unit (MMU), etc.). Such units also refer to circuits or circuitry.

The disclosed circuits/units/components and other elements illustrated in the drawings and described herein thus include hardware elements such as those described in the preceding paragraph. In many instances, the internal arrangement of hardware elements within a particular circuit may be specified by describing the function of that circuit. For example, a particular “decode unit” may be described as performing the function of “processing an opcode of an instruction and routing that instruction to one or more of a plurality of functional units,” which means that the decode unit is “configured to” perform this function. This specification of function is sufficient, to those skilled in the computer arts, to connote a set of possible structures for the circuit.

In various embodiments, as discussed in the preceding paragraph, circuits, units, and other elements defined by the functions or operations that they are configured to implement, The arrangement and such circuits/units/components with respect to each other and the manner in which they interact form a microarchitectural definition of the hardware that is ultimately manufactured in an integrated circuit or programmed into an FPGA to form a physical implementation of the microarchitectural definition. Thus, the microarchitectural definition is recognized by those of skill in the art as structure from which many physical implementations may be derived, all of which fall into the broader structure described by the microarchitectural definition. That is, a skilled artisan presented with the microarchitectural definition supplied in accordance with this disclosure may, without undue experimentation and with the application of ordinary skill, implement the structure by coding the description of the circuits/units/components in a hardware description language (HDL) such as Verilog or VHDL. The HDL description is often expressed in a fashion that may appear to be functional. But to those of skill in the art in this field, this HDL description is the manner that is used transform the structure of a circuit, unit, or component to the next level of implementational detail. Such an HDL description may take the form of behavioral code (which is typically not synthesizable), register transfer language (RTL) code (which, in contrast to behavioral code, is typically synthesizable), or structural code (e.g., a netlist specifying logic gates and their connectivity). The HDL description may subsequently be synthesized against a library of cells designed for a given integrated circuit fabrication technology, and may be modified for timing, power, and other reasons to result in a final design database that is transmitted to a foundry to generate masks and ultimately produce the integrated circuit. Some hardware circuits or portions thereof may also be custom-designed in a schematic editor and captured into the integrated circuit design along with synthesized circuitry. The integrated circuits may include transistors and other circuit elements (e.g., passive elements such as capacitors, resistors, inductors, etc.) and interconnect between the transistors and circuit elements. Some embodiments may implement multiple integrated circuits coupled together to implement the hardware circuits, and/or discrete elements may be used in some embodiments. Alternatively, the HDL design may be synthesized to a programmable logic array such as a field programmable gate array (FPGA) and may be implemented in the FPGA. This decoupling between the design of a group of circuits and the subsequent low-level implementation of these circuits commonly results in the scenario in which the circuit or logic designer never specifies a particular set of structures for the low-level implementation beyond a description of what the circuit is configured to do, as this process is performed at a different stage of the circuit implementation process.

The fact that many different low-level combinations of circuit elements may be used to implement the same specification of a circuit results in a large number of equivalent structures for that circuit. As noted, these low-level circuit implementations may vary according to changes in the fabrication technology, the foundry selected to manufacture the integrated circuit, the library of cells provided for a particular project, etc. In many cases, the choices made by different design tools or methodologies to produce these different implementations may be arbitrary.

Moreover, it is common for a single implementation of a particular functional specification of a circuit to include, for a given embodiment, a large number of devices (e.g., millions of transistors). Accordingly, the sheer volume of this information makes it impractical to provide a full recitation of the low-level structure used to implement a single embodiment, let alone the vast array of equivalent possible implementations. For this reason, the present disclosure describes structure of circuits using the functional shorthand commonly employed in the industry.

What is claimed is:

1. An apparatus, comprising:
an integrated circuit device having a transistor region above a substrate in a vertical dimension perpendicular to the substrate;
a core logic region in the transistor region, the core logic region including a plurality of functional circuits positioned in the transistor region;
a power switch region in the transistor region, the power switch region including a plurality of power switch circuits aligned linearly in a horizontal dimension in the transistor region;
a first set of one or more metal layers positioned above the transistor region in the vertical dimension;
a second set of one or more metal layers positioned above the first set of one or more metal layers in the vertical dimension;
a third set of one or more metal layers positioned above the second set of one or more metal layers in the vertical dimension;
wherein, above the power switch region in the vertical dimension, a last metal layer in the first set of one or more metal layers furthest from the transistor region includes pillar routing and remaining metal layers of the first set of one or more metal layers include mesh routing, and wherein the first set of one or more metal layers above the power switch region in the vertical dimension include at least one power supply route coupled to at least one power switch circuit; and
wherein the first set of one or more metal layers above the core logic region in the vertical dimension are absent any pillar routing or mesh routing;
wherein, above both the core logic region and the power switch region in the vertical dimension, a lowest metal layer in the second set of one or more metal layers closest to the transistor region in the vertical dimension and a last metal layer in the second set of one or more metal layers furthest from the transistor region in the vertical dimension both include mesh routing;
wherein, above both the core logic region and the power switch region in the vertical dimension, the second set of one or more metal layers includes at least two or more metal layers having pillar routing, the at least two metal layers being layers closest to the lowest metal layer in the vertical dimension;
wherein, above the power switch region in the vertical dimension, the second set of one or more metal layers includes at least one power supply route coupled to the at least one power supply route in the first set of one or more metal layers; and
wherein, above both the core logic region and the power switch region in the vertical dimension, a first metal layer in the third set of one or more metal layers closest to the transistor region in the vertical dimension includes mesh routing, the mesh routing in the first metal layer being coupled to the at least one power supply route in the second set of one or more metal layers and a power supply circuit, the mesh routing receiving a power supply voltage from the power supply circuit.

2. The apparatus of claim 1, wherein the first metal layer in the second set of one or more metal layers is a first single patterned layer with immersion lithography.

3. The apparatus of claim 1, wherein the first metal layer in the third set of one or more metal layers is a first dry lithography layer closest to the transistor region in the vertical dimension.

4. The apparatus of claim 1, wherein the mesh routings include metal structures that have lengths approximately spanning dimensions of the core logic region or the power switch region.

5. The apparatus of claim 1, wherein the pillar routings include metal structures that have lengths dimensioned as minimum lengths for landing a specified number of vias routing above or below the metal structures.

6. The apparatus of claim 1, wherein at least one intermediate metal layer in the second set of one or more metal layers above the at least two or more metal layers having pillar routing in the vertical dimension includes mesh routing.

7. The apparatus of claim 1, further comprising interconnecting metal layers in the first, second, and third sets of metal layers with a plurality of vias.

8. The apparatus of claim 1, wherein the at least one power switch circuit coupled to the at least one power supply route receives the power supply voltage from the power supply circuit through the power supply routes in the sets of metal layers.

9. An apparatus, comprising:
an integrated circuit device having a transistor region above a substrate in a vertical dimension perpendicular to the substrate;
a core logic region in the transistor region, the core logic region including a plurality of functional circuits positioned in the transistor region;
a power switch region in the transistor region, the power switch region including a plurality of power switch circuits aligned linearly in a horizontal dimension in the transistor region;
a first set of one or more metal layers positioned above the transistor region in the vertical dimension;
a second set of one or more metal layers positioned above the first set of one or more metal layers in the vertical dimension;
a third set of one or more metal layers positioned above the second set of one or more metal layers in the vertical dimension;
wherein, above the power switch region in the vertical dimension, the first set of one or more metal layers includes two or more layers of mesh routing, wherein the mesh routing in the first set of one or more metal layers include at least one power route coupled to at least one power switch circuit, the at least one power route receiving an output voltage from the at least one power switch circuit;
wherein a last metal layer of the first set of one or more metal layers furthest from the transistor region in the vertical dimension includes mesh routing coupled to the at least one power route, the mesh routing in the last metal layer having a path above both the power switch region and the core logic region in the vertical dimension; and
wherein, above the core logic region in the vertical dimension, the first set of one or more metal layers includes two or more layers of pillar routing, the pillar routing including at least one power route coupled to the mesh routing in the last metal layer of the first set of one or more metal layers; and
wherein, above the core logic region in the vertical dimension, a lowest metal layer in the first set of one or more metal layers closest to the transistor region in the vertical dimension includes mesh routing, the mesh routing in the lowest metal layer coupling the at least one power route in the two or more layers of pillar routing to at least one functional circuit in the core logic region.

10. The apparatus of claim 9, wherein a first metal layer in the second set of one or more metal layers is a first single patterned layer with immersion lithography, and wherein a first metal layer in the third set of one or more metal layers is a first dry lithography layer closest to the transistor region in the vertical dimension.

11. The apparatus of claim 9, wherein the mesh routings include metal structures that have lengths approximately spanning dimensions of the core logic region or the power switch region, and wherein the pillar routings include metal structures that have lengths dimensioned as minimum lengths for landing a specified number of vias routing above or below the metal structures.

12. The apparatus of claim 9, wherein, above the core logic region in the vertical dimension, a second furthest metal layer from the transistor region in the first set of one or more metal layers includes mesh routing that couples the at least one power route in the two or more layers of pillar routing to the mesh routing in the last metal layer of the first set of one or more metal layers.

13. The apparatus of claim 9, wherein, above the core logic region in the vertical dimension, a second furthest metal layer from the transistor region includes pillar routing that couples the at least one power route in the two or more layers of pillar routing to the mesh routing in the last metal layer of the first set of one or more metal layers.

14. The apparatus of claim 9, wherein the at least one functional circuit coupled to the at least one power route in the two or more layers of pillar routing receives the output voltage from the at least one power switch circuit through the power routes in the first set of one or more metal layers.

15. An apparatus, comprising:
an integrated circuit device having a transistor region above a substrate in a vertical dimension perpendicular to the substrate;
a core logic region in the transistor region, the core logic region including a plurality of functional circuits positioned in the transistor region;
a power switch region in the transistor region, the power switch region including a plurality of power switch circuits aligned linearly in a horizontal dimension in the transistor region;
a first set of one or more metal layers positioned above the transistor region in the vertical dimension;
a second set of one or more metal layers positioned above the first set of one or more metal layers in the vertical dimension;
a third set of one or more metal layers positioned above the second set of one or more metal layers in the vertical dimension;
wherein, above both the core logic region and the power switch region in the vertical dimension, a lowest metal layer in the second set of one or more metal layers closest to the transistor region in the vertical dimension and a last metal layer in the second set of one or more metal layers furthest from the transistor region in the vertical dimension both include mesh routing;
wherein, above the power switch region in the vertical dimension, the second set of one or more metal layers includes at least two or more metal layers having pillar routing, the at least two metal layers being layers closest to the lowest metal layer in the vertical dimension;
at least one ground supply route through the first set of one or more metal layers and the second set of one or more metal layers above the core logic region in the vertical dimension, the at least one ground supply route being coupled to at least one functional circuit; and
ground mesh routing in a first metal layer in the third set of one or more metal layers closest to the transistor region in the vertical dimension, the ground mesh routing in the first metal layer being coupled to a power supply circuit and the at least one ground supply route, the ground mesh routing receiving a ground supply voltage from the power supply circuit.

16. The apparatus of claim 15, wherein the first metal layer in the second set of one or more metal layers is a first single patterned layer with immersion lithography, and wherein a first metal layer in the third set of one or more metal layers is a first dry lithography layer closest to the transistor region in the vertical dimension.

17. The apparatus of claim 15, wherein the mesh routings include metal structures that have lengths approximately spanning dimensions of the core logic region or power switch region, and wherein the pillar routings include metal structures that have lengths dimensioned as minimum lengths for landing a specified number of vias routing above or below the metal structures.

18. The apparatus of claim 15, wherein, above the power switch region in the vertical dimension, the first set of one or more metal layers includes metal layers with mesh routing, pillar routing, or a combination thereof.

19. The apparatus of claim 15, wherein, above the core logic region in the vertical dimension, a lowest metal layer in the first set of one or more metal layers closest to the transistor region in the vertical dimension includes mesh routing and remaining metal layers in the first set of one or more metal layers include pillar routing.

20. The apparatus of claim 15, wherein, above the core logic region in the vertical dimension, remaining metal layers in the second set of one or more metal layers include pillar routing, the remaining metal layers being all the metal layers between the lowest metal layer and the last metal layer in the second set of one or more metal layers.
